(19) United States
(12) Patent Application Publication
(10) Pub. No.: US 2018/0221816 A1
(43) Pub. Date: Aug. 9, 2018

(54) PLASMA ABATEMENT OF NITROUS OXIDE FROM SEMICONDUCTOR PROCESS EFFLUENTS

(71) Applicant: Applied Materials, Inc., Santa Clara, CA (US)

(72) Inventors: Joseph A. VAN GOMPEL, Austin, TX (US); Dustin W. HO, Shanghai (CN); Zheng YUAN, Santa Clara, CA (US); James L'HEUREUX, Santa Clara, CA (US); Ryan T. DOWNEY, San Jose, CA (US)

(21) Appl. No.: 15/887,834

(22) Filed: Feb. 2, 2018

(30) Foreign Application Priority Data
Feb. 3, 2017 (CN) PCT/CN2017/072866

(51) Int. Cl. B01D 53/56; B01D 53/76; B01D 53/34; H01L 21/67; G05D 16/20

(52) U.S. Cl. CPC B01D 53/56; B01D 53/76; G05D 16/2066; H01L 21/67017; B01D 53/346

(57) ABSTRACT

Embodiments of the present disclosure generally relate techniques for abating N₂O gas present in the effluent of semiconductor manufacturing processes. In one embodiment, a method includes injecting hydrogen gas or ammonia gas into a plasma source, and an effluent containing N₂O gas and the hydrogen or ammonia gas are energized and reacted to form an abated material. By using the hydrogen gas or the ammonia gas, the destruction and removal efficiency (DRE) of the N₂O gas is at least 50 percent while the concentration of nitric oxide (NO) and/or nitrogen dioxide (NO₂) in the abated material is substantially reduced, such as at most 5000 parts per million (ppm) by volume.

### CROSS-REFERENCE TO RELATED APPLICATION(S)

This application claims the priority of PCT International Application No. PCT/CN2017/072866, filed Feb. 3, 2017, the entire contents of which are incorporated by reference herein.

### BACKGROUND

### Field

Embodiments of the present disclosure generally relate to abatement for semiconductor processing equipment. More particularly, embodiments of the present disclosure relate to techniques for abating nitrous oxide (N₂O) gas present in the effluent of semiconductor manufacturing processes.

### Description of the Related Art

Effluent produced during semiconductor manufacturing processes includes many compounds which must be abated or treated before disposal, due to regulatory requirements and environmental and safety concerns. In some semiconductor manufacturing processes, N₂O gas is used as the oxygen source for chemical vapor deposition (CVD) of silicon oxynitride (doped or undoped), silicon oxide, low-k dielectrics, or fluorosilicate glass, where the N₂O gas is used in conjunction with other deposition gases such as silane (SiH₄), dichlorosilane (SiH₂Cl₂), tetraethyl orthosilicate (TEOS), silicon tetrafluoride (SiF₄), and/or ammonia (NH₃). N₂O gas is also used in diffusion, rapid thermal processing and chamber treatment. In some processes, halogen containing compounds such as perfluorinated compound (PFC) are used, for example, in etching or cleaning processes.

Current abatement technology focuses on abating PFCs. However, there are no appropriate methods for abating N₂O gas. Thus, an improved method is needed for abating N₂O gas.

### SUMMARY

Embodiments of the present disclosure generally relate techniques for abating N₂O gas present in the effluent of semiconductor manufacturing processes. In one embodiment, a method for abating an effluent containing nitrous oxide gas including flowing the effluent containing nitrous oxide gas into a plasma source, injecting hydrogen gas into the plasma source, and energizing and reacting the effluent and the hydrogen gas to form an abated material, wherein a destruction and removal efficiency of the nitrous oxide gas is at least 50 percent and a concentration of nitric oxide or nitrogen dioxide in the abated material is at most 5000 parts per million by volume.

In another embodiment, a method for abating an effluent containing nitrous oxide gas including flowing the effluent containing nitrous oxide gas into a plasma source, injecting ammonia gas into the plasma source, and energizing and reacting the effluent and the ammonia gas to form an abated material, wherein a destruction and removal efficiency of the nitrous oxide gas is at least 50 percent and a concentration of nitric oxide or nitrogen dioxide in the abated material is at most 5000 parts per million by volume.

In another embodiment, a method for abating an effluent containing nitrous oxide gas including flowing the effluent containing nitrous oxide gas into a plasma source, wherein the nitrous oxide gas is flowed at a first flow rate, injecting a gas mixture into the plasma source, wherein the gas mixture is injected at a second flow rate, wherein the second flow rate is greater than the first flow rate, and energizing and reacting the effluent and the gas mixture to form an abated material, wherein a concentration of nitric oxide or nitrogen dioxide in the abated material is at most 5000 parts per million by volume.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only typical embodiments of this disclosure and are therefore not to be considered limiting of its scope, for the disclosure may admit to other equally effective embodiments.

FIG. 1 is a schematic diagram of a processing system according to one embodiment described herein.

FIG. 2 is a flow diagram illustrating a method for abating nitrous oxide gas containing effluent from a processing chamber, according to one embodiment described herein.

To facilitate understanding, identical reference numerals have been used, wherever possible, to designate identical elements that are common to the Figures. Additionally, elements of one embodiment may be advantageously adapted for utilization in other embodiments described herein.

### DETAILED DESCRIPTION

Embodiments of the present disclosure generally relate techniques for abating N₂O gas present in the effluent of semiconductor manufacturing processes. In one embodiment, a method includes injecting hydrogen gas or ammonia gas into a plasma source, and an effluent containing N₂O gas and the hydrogen or ammonia gas are energized and reacted to form an abated material. By using the hydrogen gas or the ammonia gas, the destruction and removal efficiency (DRE) of the N₂O gas is at least 50 percent while the concentration of nitric oxide (NO) and/or nitrogen dioxide (NO₂) in the abated material is significantly reduced, such as at most 5000 parts per million (ppm) by volume.

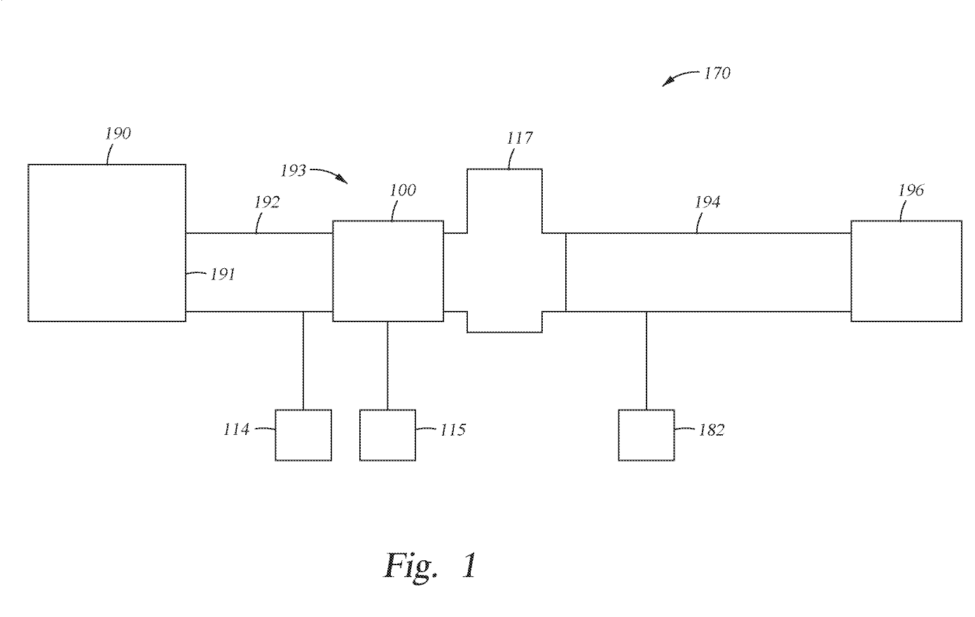

FIG. 1 is a schematic side view of a vacuum processing system 170. The vacuum processing system 170 includes at least a vacuum processing chamber 190, a vacuum pump 196, and a foreline assembly 193 connecting the vacuum processing chamber 190 and the vacuum pump 196. The vacuum processing chamber 190 is generally configured to perform at least one integrated circuit manufacturing process, such as a deposition process, an etch process, a plasma treatment process, a preclean process, an ion implant process, or other integrated circuit manufacturing process. The process performed in the vacuum processing chamber 190 may be plasma assisted. For example, the process performed in the vacuum processing chamber 190 may be plasma deposition process for depositing a silicon-based material. The foreline assembly 193 includes at least a first conduit 192 coupled to a chamber exhaust port 191 of the vacuum processing chamber 190, a plasma source 100 coupled to the first conduit 192, and a second conduit 194 coupled to the vacuum pump 196. One or more abatement reagent sources 114 are coupled to foreline assembly 193. In some embodiments, the one or more abatement reagent sources 114 are coupled to the first conduit 192. In some embodiments, the one or more abatement reagent sources 114 are coupled to the plasma source 100. The abatement reagent sources 114 provide one or more abatement reagents into the first conduit 192 or the plasma source 100 which may be energized to react with or otherwise assist converting the materials exiting the vacuum processing chamber 190 into a more environmentally and/or process equipment friendly composition. In some embodiments, one or more abatement reagents include hydrogen gas or ammonia gas. Optionally, a purge gas source 115 may be coupled to the plasma source 100 for reducing deposition on components inside the plasma source 100.

The foreline assembly 193 may further include an exhaust cooling apparatus 117. The exhaust cooling apparatus 117 may be coupled to the plasma source 100 downstream of the plasma source 100 for reducing the temperature of the exhaust exiting the plasma source 100. The second conduit 194 may be coupled to the exhaust cooling apparatus 117.

Optionally, a pressure regulating module 182 may be coupled to at least one of the plasma source 100 or second conduit 194. The pressure regulating module 182 injects a pressure regulating gas, such as Ar, N, or other suitable gas which allows the pressure within the plasma source 100 to be better controlled, and thereby provide more efficient abatement performance. In one example, the pressure regulating module 182 is a part of the abatement system 193.

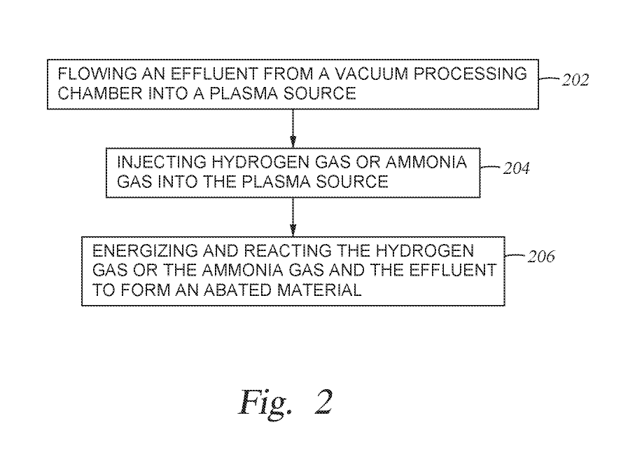

FIG. 2 is a flow diagram illustrating a method 200 for abating nitrous oxide gas containing effluent from a processing chamber, according to one embodiment described herein. The method 200 starts with block 202, in which an effluent is flowed from a vacuum processing chamber into a plasma source. The vacuum processing chamber may be the vacuum processing chamber 190 shown in FIG. 1, and the effluent includes N₂O gas. The vacuum processing chamber may be utilized to perform a deposition process, in which a silicon containing gas and N₂O gas are reacted to form a silicon oxide layer, a silicon oxynitride layer, a low-k dielectric layer, or fluorosilicate glass on a substrate disposed in the vacuum processing chamber. The silicon containing gas may be silane, TEOS, SiF₄, or SiH₂Cl₂. The amount of N₂O gas used during the deposition process may be more than the amount of silicon containing gas, leading to an amount of N₂O gas in the effluent exiting the vacuum processing chamber. The plasma source may be the plasma source 100 shown in FIG. 1.

Next, at block 204, hydrogen gas, ammonia gas, or a mixture of hydrogen gas and ammonia gas is injected into the plasma source as an abatement reagent. The abatement reagent may be oxygen free. In some embodiments, the hydrogen gas and the ammonia gas are sequentially injected into the plasma source. In one embodiment, the hydrogen gas is injected into the plasma source followed by injecting the ammonia gas into the plasma source. For example, the flow of hydrogen gas injected into the plasma source may be terminated prior to injecting the ammonia gas into the plasma source. In another example, the flow of hydrogen gas injected into the plasma source may be terminated after commencement of injecting the ammonia gas into the plasma source. In another embodiment, the ammonia gas is injected into the plasma source followed by injecting the hydrogen gas into the plasma source. The flow rate of the hydrogen gas or ammonia gas is higher than the flow rate of the N₂O gas. In one embodiment, the flow rate of the hydrogen gas or ammonia gas is about twice the flow rate of the N₂O gas. In one embodiment, the flow rate of the N₂O gas ranges from about 1 standard liter per minute (slm) to about 35 slm. The hydrogen gas or ammonia gas may be injected into the plasma source from an abatement reagent source, such as the one or more abatement reagent source 114 shown in FIG. 1. Next, the hydrogen gas or the ammonia gas and the effluent are energized and reacted in the plasma source to form an abated material, as shown at block 206.

Conventional abatement reagents, such as water vapor and oxygen gas, lead to the formation of NO and NO₂, which are major pollutants in the atmosphere, when used to abate effluent containing N₂O gas. The concentration of NO or NO₂ in the abated material when water vapor or oxygen gas is used as the abatement reagent is high, such as over 10,000 ppm by volume.

When hydrogen gas or ammonia gas is used as the abatement reagent, the DRE of the N₂O gas is high, such as at least 50 percent, while the concentration of NO or NO₂ in the abated material is substantially reduced, such as at most 5000 ppm by volume. In one embodiment, the DRE of N₂O gas is 60 percent. In one embodiment, a power ranging from about 4 kW to about 6 kW is supplied to the plasma source to energize the effluent and the hydrogen gas or the ammonia gas.

By utilizing hydrogen gas or ammonia gas as the abatement reagent when abating an effluent containing N₂O gas, the DRE of the N₂O gas is high while the formation of NO and NO₂ is substantially reduced.

While the foregoing is directed to embodiments of the disclosed devices, methods and systems, other and further embodiments of the disclosed devices, methods and systems may be devised without departing from the basic scope thereof, and the scope thereof is determined by the claims that follow. cm What is claimed is:

1. A method for abating an effluent containing nitrous oxide gas, comprising:
flowing the effluent containing nitrous oxide gas into a plasma source;
injecting hydrogen gas into the plasma source; and
energizing and reacting the effluent and the hydrogen gas to form an abated material, wherein a destruction and removal efficiency of the nitrous oxide gas is at least 50 percent and a concentration of nitric oxide or nitrogen dioxide in the abated material is at most 5000 parts per million by volume.

2. The method of claim 1, wherein the effluent is flowed from a processing chamber into the plasma source.

3. The method of claim 2, further comprising a deposition process performed in the processing chamber, wherein the deposition process comprises reacting a silicon containing gas and nitrous oxide gas to form a silicon oxide or a silicon oxynitride layer.

4. The method of claim 3, wherein the silicon containing gas is silane.

5. The method of claim 1, wherein the nitrous oxide gas is flowed into the plasma source at a first flow rate and the hydrogen gas is injected into the plasma source at a second flow rate, wherein the second flow rate is higher than the first flow rate.

6. The method of claim 5, wherein the second flow rate is about twice the first flow rate.

7. The method of claim 6, wherein the first flow rate ranges from about 1 standard liter per minute to about 35 standard liter per minute.

8. A method for abating an effluent containing nitrous oxide gas, comprising:
flowing the effluent containing nitrous oxide gas into a plasma source;
injecting ammonia gas into the plasma source; and
energizing and reacting the effluent and the ammonia gas to form an abated material, wherein a destruction and removal efficiency of the nitrous oxide gas is at least 50 percent and a concentration of nitric oxide or nitrogen dioxide in the abated material is at most 5000 parts per million.

9. The method of claim 8, wherein the effluent is flowed from a processing chamber into the plasma source.

10. The method of claim 9, further comprising a deposition process performed in the processing chamber, wherein the deposition process comprises reacting a silicon containing gas and nitrous oxide gas to form a silicon oxide or a silicon oxynitride layer.

11. The method of claim 10, wherein the silicon containing gas is silane.

12. The method of claim 8, wherein the nitrous oxide gas is flowed into the plasma source at a first flow rate and the ammonia gas is injected into the plasma source at a second flow rate, wherein the second flow rate is higher than the first flow rate.

13. The method of claim 12, wherein the second flow rate is about twice the first flow rate.

14. The method of claim 13, wherein the first flow rate ranges from about 1 standard liter per minute to about 35 standard liter per minute.

15. A method for abating an effluent containing nitrous oxide gas, comprising:
flowing the effluent containing nitrous oxide gas into a plasma source, wherein the nitrous oxide gas is flowed at a first flow rate;
injecting a gas mixture into the plasma source, wherein the gas mixture is injected at a second flow rate, wherein the second flow rate is greater than the first flow rate; and
energizing and reacting the effluent and the gas mixture to form an abated material, wherein a concentration of nitric oxide or nitrogen dioxide in the abated material is at most 5000 parts per million.

16. The method of claim 15, wherein the effluent is flowed from a processing chamber into the plasma source.

17. The method of claim 16, wherein the gas mixture comprises hydrogen gas and ammonia gas.

18. The method of claim 15, wherein the gas mixture is oxygen free.

19. The method of claim 15, wherein the second flow rate is about twice the first flow rate.

20. The method of claim 19, wherein the first flow rate ranges from about 1 standard liter per minute to about 35 standard liter per minute.
